(19) United States
(12) Patent Application Publication
(10) Pub. No.: US 2006/0267619 A1
(43) Pub. Date: Nov. 30, 2006

(54) Transfer device

(75) Inventors: Yu-Ping Wu, Shenzhen (CN); Lian-Zhong Gong, Shenzhen (CN)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/442,778

(22) Filed: May 30, 2006

(30) Foreign Application Priority Data
May 27, 2005 (TW) 94208717

(51) Int. Cl. G01R 31/02

(52) U.S. Cl. 324/764

(57) ABSTRACT

An exemplary transfer device (20) includes a testing table (21), a transfer plate (22) slidably positioned on the testing table, and two positioning clamps (23) arranged on the transfer table. The positioning clamps are configured for clamping a liquid crystal display therebetween. The positioning clamps can prevent vibration and movement of an LCD to be tested, when the LCD is positioned on the transfer table and transferred along the testing table by sliding of the transfer table. This speeds correct positioning of the LCD for testing, and helps promote the efficiency and veracity of the testing process.

### FIELD OF THE INVENTION

The present invention relates to transfer devices, and more particularly to a transfer device for promoting the efficiency of testing liquid crystal displays (LCDs) in manufacturing.

### BACKGROUND

In a typical process of manufacturing LCDs, testing and controlling the quality of each LCD is important. Characteristics of images shown by a display of the LCD are tested, such characteristics including for example brightness and uniformity of display. Generally, a transfer device is needed for transferring the LCD to a stable position on a testing device. This can promote the efficiency and effectiveness of the testing.

FIG. 4 is a schematic, isometric view of a conventional transfer device 100, together with two LCDs 180 positioned thereon. The transfer device 100 includes a testing table 110, and a transfer table 120 movably arranged on the testing table 110. The LCDs 180 are to be tested, and are positioned on the transfer table 120. The LCDs 180 are transferred to the testing equipment by sliding movement of the transfer table 120 along the testing table 110.

A brightness test is one typical test performed. In such test, a display panel 181 of each LCD 180 needs to be maintained in a vertical position relative to the testing equipment. However, the display panel 181 is liable to vibrate during the transferring process. When this happens, typically, an operator needs to manually correct the position of each individual display panel 181. This increases the time needed for testing, and decreases the efficiency of manufacturing.

What is needed, therefore, is a transfer device that overcomes the above-described deficiencies.

### SUMMARY

A transfer device includes a testing table, a transfer table slidably positioned on the testing table, and at least one positioning clamp arranged on the transfer table. The at least one positioning clamp is configured for clamping a liquid crystal display.

In a preferred embodiment, two positioning clamps are provided. The positioning clamps can prevent vibration and movement of an LCD to be tested, when the LCD is positioned on the transfer table and transferred along the testing table by sliding of the transfer table. This speeds correct positioning of the LCD for testing, and helps promote the efficiency and veracity of the testing process.

Other advantages and novel features of preferred embodiments will become more apparent from the following detailed description when taken in conjunction with the accompanying drawings.

### BRIEF DESCRIPTION OF THE DRAWINGS

FIG. 1 is a schematic, exploded, isometric view of a transfer table of a transfer device according to an exemplary embodiment of the present invention, together with two LCDs.

FIG. 2 is an assembled view of the transfer table of FIG. 1, showing the LCDs held by the transfer table.

FIG. 3 is similar to FIG. 2, but showing the transfer table installed on a testing table (only partially shown), the transfer table and the testing table constituting the transfer device according to the exemplary embodiment of the present invention.

FIG. 4 is a schematic, isometric view of a conventional transfer device, showing only part of a testing table thereof, and also showing two LCDs positioned on a transfer table thereof.

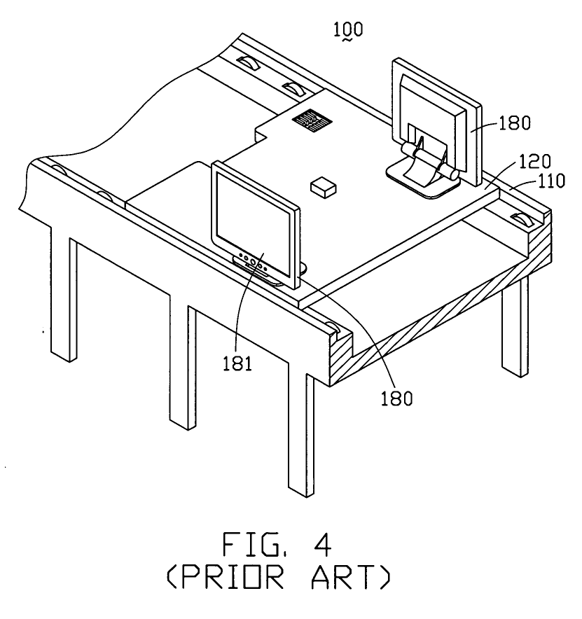

### DETAILED DESCRIPTION OF PREFERRED EMBODIMENTS

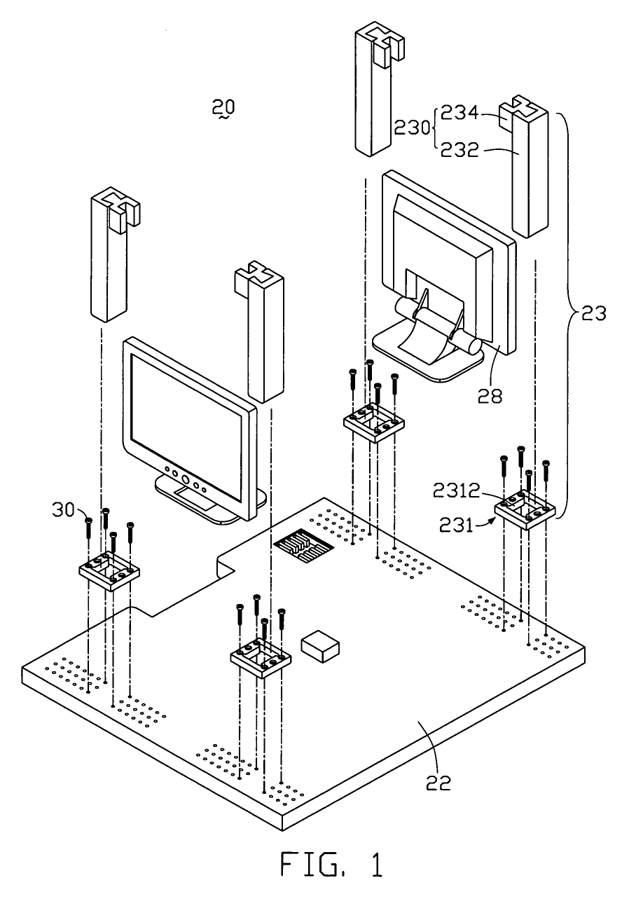

As shown in FIG. 1, a transfer table 20 includes a transfer plate 22 and a plurality of positioning clamps 23.

Each of the positioning clamps 23 includes a clamping portion 230 and a locating portion 231. The clamping portion 230 includes a supporting pole 232 and a clamping block 234. The locating portion 231 includes a central positioning opening 2312. The locating portion 231 can be fixed on the transfer plate 22 by fasteners such as bolts 30, which are inserted through a plurality of threaded holes (not labeled) of the locating portion 231 and engaged in selected threaded holes (not labeled) of the transfer plate 22.

Each clamping block 234 is fixed in a top end of the corresponding supporting pole 232. The clamping block 234 includes a jaw, with a shape of the jaw matching a shape of a frame of an LCD 28 to be tested. Thus, the configurations of the two clamping blocks 234 can firmly fix the LCD 28 therebetween. The supporting pole 232 and the positioning opening 2312 of the corresponding locating portion 231 have matching sizes, whereby a bottom end of the supporting pole 232 can be firmly clamped in the positioning opening 2312.

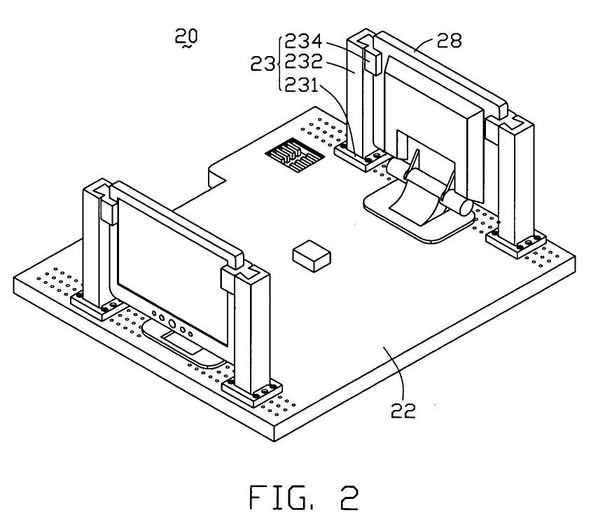

In use, as shown in FIG. 2, the positioning clamps 23 are attached on the transfer plate 22, and the LCD 28 is positioned and held between the clamping blocks 234. The locating portions 231, the supporting poles 232, and the clamping blocks 234 cooperatively hold the LCD 18 in a desired vertical position.

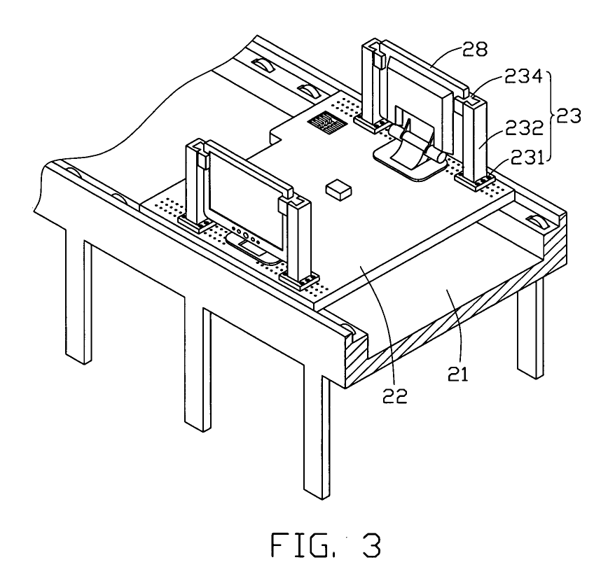

Referring to FIG. 3, the transfer plate 22 may be slid to each testing station along a testing table 21. The LCD 28 is firmly held in position throughout such movement, without the need for individual manual correction by an operator. Thus the LCD 28 can be set to the correct position for testing directly.

If desired, the supporting poles 232 and the clamping blocks 234 can be pulled out from the locating portions 231 if the LCD 28 does not need to be precisely positioned.

A material of the locating portions 231 and the supporting poles 232 can be anti-electrostatic material such as Bakelite™, to avoid generating electrostatic charge. A material of the clamping blocks 234 can be a soft material such as rubber, to avoid scraping the LCD 28.

In summary, the positioning clamps 23 can prevent vibration and movement of the LCD 28 when it is transferred along the testing table 21. This speeds correct positioning of the LCD 28 for testing, and helps promote the efficiency and veracity of the testing process.

It is to be understood, however, that even though numerous characteristics and advantages of various embodiments have been set out in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A transfer device, comprising:
a testing table;
a transfer table slidably positioned on the testing table; and
at least one positioning clamp arranged on the transfer table, the at least one positioning clamp configured for clamping a liquid crystal display.

2. The transfer device as claimed in claim 1, wherein the at least one positioning clamp further comprises a clamping portion and a locating portion.

3. The transfer device as claimed in claim 2, wherein the locating portion comprises a positioning opening.

4. The transfer device as claimed in claim 3, wherein the clamping portion comprises a supporting pole and a clamping block.

5. The transfer device as claimed in claim 4, wherein the clamping block is fixed in one end of the supporting pole, and another end of the supporting pole is engaged in the positioning opening of the locating portion.

6. The transfer device as claimed in claim 3, wherein a material of each of the locating portion and the supporting pole is anti-electrostatic.

7. The transfer device as claimed in claim 3, wherein a material of the clamping block is soft.

8. The transfer device as claimed in claim 7, wherein the material is rubber.

9. A transfer device, comprising:
a testing table;
a transfer table positioned on the testing table and slidable along a first direction; and
at least one positioning rail arranged on the transfer table, so as to allow an LCD to positioned thereto and slidable along a second direction perpendicular to said first direction.

10. A transfer device assembly comprising:
a testing table;
a transfer table positioned on the testing table and slidable along a first direction; and
an LCD positioned upon the transfer table and defining a main plane with a normal line thereto extending along a second direction perpendicular to said first direction; wherein
a device fixed to the transfer table and holds said LCD in position without changing the second direction.
